(19) United States
(12) Patent Application Publication
(10) Pub. No.: US 2001/0055458 A1
(43) Pub. Date: Dec. 27, 2001

(54) Sheet-like light emitting display and method

(76) Inventor: Judith A. Ladd, Hamilton, NJ (US)

Correspondence Address: DANN DORFMAN HERRELL & SKILLMAN, SUITE 720, 1601 MARKET STREET, PHILADELPHIA, PA, 19103-2307, US

(21) Appl. No.: 09/879,275

(22) Filed: Jun. 12, 2001

Related U.S. Application Data
(60) Provisional application No. 60/213,568, filed on Jun. 22, 2000.

(51) Int. Cl. G02B 6/10

(52) U.S. Cl. 385/129; 385/31; 385/901

(57) ABSTRACT

A light-emitting display comprises a sheet having a number of light-emitting elements disposed along the length of raised features on one surface thereof. The light-emitting elements include a patterned hole injecting electrode, an electro-luminescent material, such as an OLED material, and a patterned electron injecting electrode, deposited on the sheet. Ones of the hole injecting electrodes are connected together by electrical conductors disposed in elongated recesses between the raised features on the one surface. Electrical contacts connect to the electron injecting electrode and may be segments thereon or may be strips disposed transverse to the elongated recesses.

This Application claims the benefit of U.S. Provisional Application Ser. No. 60/213,568 filed Jun. 22, 2000.

The present invention relates to a light emitting display and, in particular, to a sheet-like light emitting display and method.

Conventional image displays for large image sizes, e.g., images exceeding about 750-1000 cm (about 30-40 inches), suffer the well known issues of requiring a display having a very substantial depth in the case of cathode ray tube displays and of alignment and image registration in the case of projection displays, as well as high cost. Such conventional displays, as well as more recent relatively-thin plasma display panels, are constructed in a manner that non-uniformity of only a few pixels or relatively small regions of the conventional display can have a significant deleterious effect on overall image quality that would be noticeable by a typical viewer and so renders the entire display unsatisfactory. Because such defects are not detectable until the display device is substantially complete and such display devices are not generally repairable, the entire display device is typically scrapped at great cost.

Thus there is a need for a display, particularly for a thin, large-area image display. One such display is a display based on a plurality of fibers carrying light-emitting elements disposed along their lengths (i.e. often referred to as a light-emitting fiber) wherein the fibers are disposed side-by-side in array. One such display and the light-emitting fibers therefor are described, for example, in published patent applications WO 00/51192 entitled “DISPLAY DEVICE” published Aug. 31, 2001 and WO 00/5602 entitled “FIBER CARRYING LIGHT EMITTING ELEMENTS” published Aug. 31, 2001.

While such fiber-based display devices have certain advantages such as the individual fibers being testable before assembly into a display and being conveniently made, many fibers are required for a large-size display.

Accordingly, there is a need for a sheet-like light-emitting display that is susceptible to efficient manufacture while retaining at least some of the benefits of a fiber-based display.

To this end, the display of the present invention comprises an optically transparent material having a broad surface having a plurality of elongated recesses therein defining raised portions therebetween, and a first electrode layer disposed on the raised portions of the broad surface of the optically transparent material, wherein the electrode layer includes an optically-transparent electrically conductive material. A plurality of elongated electrical conductors is disposed in the plurality of elongated recesses of the broad surface of the optically transparent material, wherein a respective one of the elongated electrical conductors is in electrical contact with the electrode layer on one of the raised portions. A light-emitting material is disposed at least on the first electrode layer on the raised portions of the optically-transparent material, and a plurality of electrical contacts is disposed on the light-emitting material on the raised portions of the optically-transparent material, wherein the light-emitting material disposed between the electrode layer and a given one of the electrical contacts emits light responsive to an electrical signal applied between the electrode layer and the corresponding one electrical contact.

According to a further aspect, a method for making a light-emitting fiber having a plurality of light-emitting elements thereon comprises:

providing a sheet of electrically insulating material having on a first surface thereof a plurality of elongated recesses defining ridges therebetween;

depositing first electrodes at least on the ridges of the first surface;

placing electrically conductive material in the elongated recesses and in electrical contact with a proximal one of the first electrodes;

depositing a light-emitting material at least on the first electrodes; and

depositing a pattern of electrical contacts on the light-emitting material and substantially overlying the first electrodes.

### BRIEF DESCRIPTION OF THE DRAWING

The detailed description of the preferred embodiments of the present invention will be more easily and better understood when read in conjunction with the FIGURES of the Drawing which include:

FIG. 1 is an isometric schematic diagram illustrating an exemplary sheet of material suitable for a display in accordance with the invention;

FIG. 2 is an end view schematic diagram illustrating an exemplary arrangement and a certain step in a sequence of exemplary steps for making a display in accordance with the invention;

FIGS. 3A and 3B are plan view schematic diagrams illustrating alternative embodiments of the arrangement shown in FIG. 2;

FIG. 4 is an end view schematic diagram illustrating a certain step in a sequence of exemplary steps subsequent to the exemplary step of FIG. 2 and illustrating an exemplary display in accordance with the invention;

FIGS. 5A and 5B are plan view schematic diagrams illustrating alternative embodiments of the exemplary display shown in FIG. 4;

FIG. 6 is an end view schematic diagram illustrating an alternative exemplary arrangement and a certain alternative step in a sequence of exemplary steps for making a display in accordance with the invention; and

FIG. 7 is an end view schematic diagram illustrating a certain alternative step in a sequence of exemplary steps subsequent to the exemplary step of FIG. 6 and illustrating an exemplary display in accordance with the invention.

In the Drawing, where an element or feature is shown in more than one drawing figure, the same alphanumeric designation may be used to designate such element or feature in each figure, and where a closely related or modified element is shown in a figure, the same alphanumerical designation primed may be used to designate the modified element or feature. Similarly, similar elements or features may be designated by like alphanumeric designations in different figures of the Drawing and with similar nomenclature in the specification, but in the Drawing are preceded by digits unique to the embodiment described. It is noted that, according to common practice, the various features of the drawing are not to scale, and the dimensions of the various features are arbitrarily expanded or reduced for clarity.

### DESCRIPTION OF THE PREFERRED EMBODIMENT

In accordance with the invention, a light-emitting display 90 has a plurality of light-emitting elements 80 disposed on a broad surface 12 of a sheet 10 of electrically insulating material. Light-emitting elements 80 include an electro-luminescent material, preferably an Organic Light-Emitting Diode (OLED) material, disposed between suitable electrodes.

Each light-emitting element or OLED “stack” 80 includes at least a hole injecting electrode layer 20, a layer of light-emitting material 40 and an electron injector electrode 50, and is independently operable to produce one pixel of the image or information to be displayed. Alternatively light emission can occur in the electron (or hole) transport material in a region near the boundary with the hole (or electron) transport layer. In a color display, three physical pixel elements 80 may each produce one of three color sub-pixels that emit light of three different colors to together produce one color pixel of a color image. Such pixel elements 80 may be referred to a the red pixel, the green pixel and the blue pixel, for convenience.

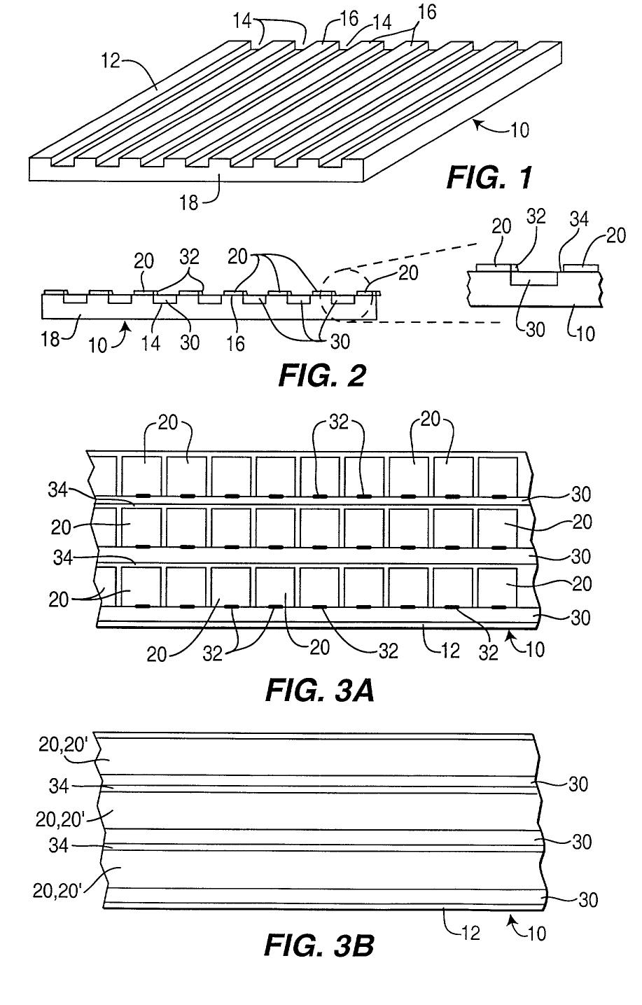

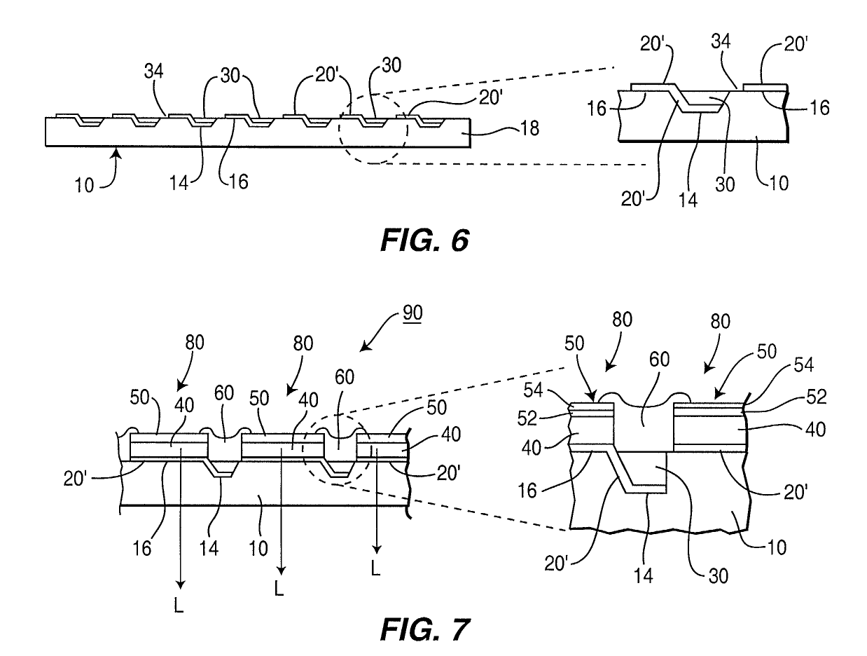

FIGS. 1 through 5A/5B are schematic diagrams illustrating a sequence of steps in the fabrication of a light-emitting display 90 including the forming of light-emitting elements 80 on one surface thereof, and illustrating the light-emitting display 90 so made. FIGS. 6-7 are schematic diagrams illustrating alternative steps and an alternative embodiment of light-emitting display 90. Only a portion of sheet 10 and/or light-emitting display 90 is shown in FIGS. 2-7 which each include an end/cross-sectional view or a top/plan view.

FIG. 1 is an isometric schematic diagram illustrating an exemplary sheet 10 or other planar substrate of material suitable for a display 90 in accordance with the invention. A sheet 10 or other elongated member of an optically transmissive material is provided. Sheet 10 has a broad surface 12, also referred to as a top surface, in which are a plurality features including elongated recesses defining raised portions therebetween. Preferably such elongated recesses include substantially parallel grooves 14 defining a plurality of substantially parallel raised portions including ridges or lands 16 therebetween.

Light-emitting elements 80 are fabricated on top surface 12 of sheet 10 which is of conventional optically transmissive material, such as glass or polymer, borosilicate glass, soda-lime glass, quartz, sapphire, plastic, polymethyl-methacrylate (PMMA), polycarbonate, acrylic, Mylar, polyester, polyimide or other suitable electrically insulating material. Grooves 14 in sheet 10 may be formed by any convenient method, such as by extrusion, pressing, embossing, machining (e.g., laser or mechanical machining), grinding, etching, and the like, and open at end 18 thereof.

FIG. 2 is an end view schematic diagram and FIGS. 3A and 3B are plan view schematic diagrams illustrating an exemplary arrangement and a certain step in a sequence of exemplary steps for making a display 90 in accordance with the invention. A thin layer of an optically transmissive, electrically-conductive material 20 is deposited at least on the lands or ridges 16 of top surface 12 of sheet 10 and may be provided as either segments 20 as illustrated in FIG. 3A or as strips 20′ as illustrated in FIG. 3B, as is convenient. Each conductor 20 may extend or encroach into one of the grooves 14 contiguous the land 16 on which it is disposed, but is spaced apart from the other groove 14 contiguous thereto thereby defining an insulating gap 34, as may be seen in the expanded insert of FIG. 2, for example. Conductive layer 20, such as indium tin oxide (ITO), tin oxide, zinc oxide, a noble metal, combinations thereof, or another transparent hole-injecting material, serves as the hole injecting electrode of a later-completed OLED light-emitting element or stack 80, and may be applied by mask deposition or other suitable method. Layer 20 may also include transparent conductive polymers, such as PEDT, polyaniline, and polythiophane.

Grooves 14 are filled with an electrically conductive material to form in grooves 14 a plurality of substantially parallel electrical conductors or buses 30 that extend substantially the entire length thereof. Each conductor 30 is in electrical contact with the ITO layer 20, 20′ on one of the lands 16 contiguous thereto, but is insulated by gap 34 from the other one of the contiguous lands 16. Conductor 30 is preferably highly electrically conductive, and may be formed of an electrically-conductive ink, epoxy or paste, or of a metal such as aluminum, copper, gold, chromium/gold (Cr Au), silver, or tungsten, deposited such as by evaporation, sputtering, screen printing or otherwise placed into grooves 14 through a mask or by any other convenient method. The width of insulating gap 34 along the edges of ITO layer 20, 20′ is typically as narrow as tolerances and processing allow, so long as sufficient width is present for providing sufficient insulating properties.

Electrical connection between ITO layer 20, 20′ and conductor 30 may be provided by ITO layer 20, 20′ extending into grooves 14 or by connections 32 therebetween, such as by a small drop or bump or a short line of conductive material such as solder or electrically-conductive epoxy or adhesive applied thereto. Conductive bus 30 makes electrical contact to ITO layer 20 for providing an electrical connection of relatively high electrical conductivity between the portion of hole injecting electrode 20 associated with each light-emitting element 80 and an input connection at one or both ends 18 of optical sheet 10.

Particularly in large displays, the lengths of conductor 30 may become long and the resistance of a thin-film or other deposited conductor 30 may be higher than desired. Conductor 30 may be made thicker by increasing the depth of grooves 14 which are preferably substantially narrower than are lands 16. Preferably, the conductive material of layer 20, conductors 30 and the material of sheet 10 are selected for having respective coefficients of thermal expansion (CTE) that are sufficiently close in value to avoid undesirable stress at the interface(s) therebetween.

It is noted that the deposition of conductor layer 20, 20′ may either precede or follow the forming of grooves 14 in sheet 10 and may either precede of follow the forming of conductors 30, as may be convenient. Also preferably, the material of sheet 10 and/or of layer 20 is relatively impervious to penetration by water or oxygen so as to protect the OLED material 40 to be deposited thereon, or it could be rendered impervious by being coated with a layer of a suitable impervious protecting material.

As thus far described, lines of ITO electrode segments 20 of ITO electrodes or strips of ITO electrodes 20′ are disposed on lands 16 each of which is contiguous to and in electrical contact with a respective elongated conductor 30 disposed in a groove 14 contiguous the land 16, as shown in FIGS. 2, 3A and 3B.

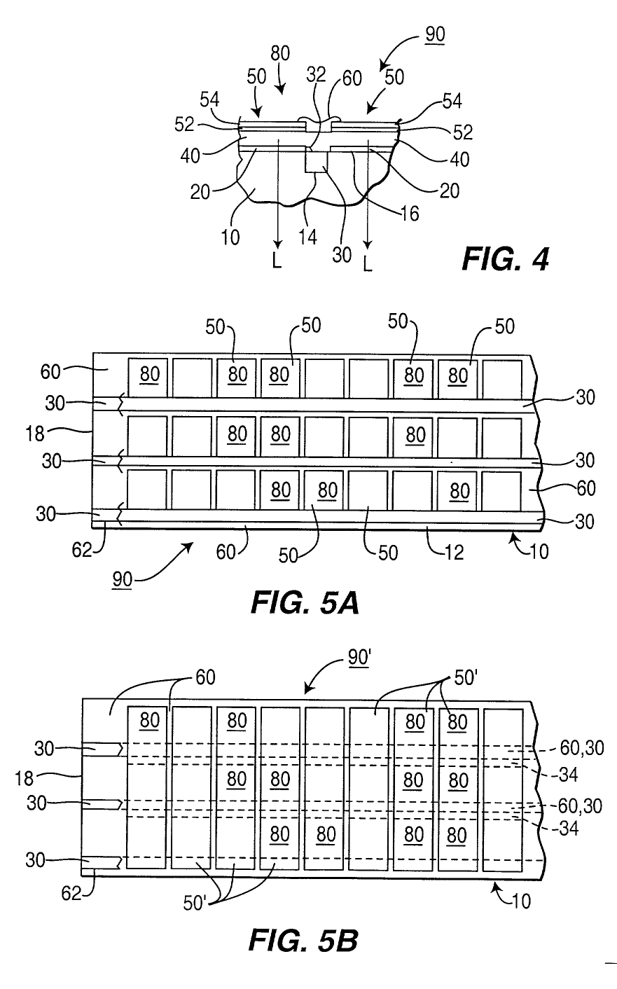

FIG. 4 is an end view schematic diagram and FIGS. 5A and 5B are plan view schematic diagrams illustrating a certain step in a sequence of exemplary steps subsequent to the exemplary step of FIG. 2 and illustrating an exemplary display 90 and an alternative display 90′ in accordance with the invention. Next, a layer 40 of OLED material is deposited on ITO layer 20 at least on the raised ridges or lands 16 of sheet 10. In the simplest form for fabrication, OLED layer 40 is continuous over ITO layer 20, 20′ on sheet 10, but it may be deposited as segments 40 each overlying a respective segment or pixel area 20 of ITO layer 20. OLED layer or stack 40 typically does not overlie a region near the end 18 of sheet 10 whereat an opening 62 exposing the end of conductor 30 and/or ITO layer 20 may be provided for making electrical connection thereto.

OLED stack 40 typically includes several different layers of material, each typically having a thickness of about 500 Å, or more or less. Certain layers thereof, such as the hole transport layer and the electron transport layer may be deposited as a continuous sheet, as by roll coating or through a mask as desired. For a monochrome display, the light-emitting material may also be a continuous layer. For a color display, however, the emitter materials producing different colors of light are deposited through a sequence of complementary masks in a pattern or grouping of different colors materials. Alternatively to a sequence of complementary masks, a mask for one color material may be sequentially stepped along and utilized for depositing the sequence of colored materials. Preferably, OLED layer 40 completely covers at least the areas of ITO layer 20 corresponding to a light-emitting element 80.

A contact 50 is provided on the top of OLED layer 40 for each one of the light-emitting elements 80 formed. Contact 50 typically comprises segmented layer 52 of electron injecting material deposited on OLED stack 40, typically through the same mask that is utilized for deposition of the OLED hole transport and electron transport layers of OLED stack 40 where such are segmented or patterned. A relatively durable conductive segmented contact layer 54 is similarly deposited onto segmented electrode layer 52 with the segments of layers 52 and 54 in registration, as illustrated in FIG. 5A, although the segments of layer 54 are typically slightly larger than those of layer 52. The segments of layer 54 extend slightly beyond the edges of patterned ITO layer 20 so as to overlie the OLED layer 40 and are surrounded by an insulation layer 60 for surrounding and insulating OLED layer 40, thereby to retard or prevent moisture, oxygen and other contaminants from reaching OLED material 40.

Each “stack” of hole-injecting layer 20, light-emitting material 40 and electron-injecting material 52 provides a light-emitting element 80 to which electrical control signals are applied via conductors 20/30 and 52/54 for causing light-emitting elements 80 to emit light. The electrical control signals applied via conductors 20/30 are usually referred to as “row selection” signals or “select signals” where conductors 30 are disposed horizontally in a display, and the electrical control signals applied via conductors 52/54 are referred to as “column select” signals or as “data signals” because their amplitude is controlled to affect the amount of light emitted by light-emitting elements 80.

The breaks between adjacent ones of the segments of electrode layer 52 expose portions of OLED layer 40 not part of light-emitting elements 80 onto which contact layer 54 may extend for defining a contact region at which electrical connection can be made to the electron-injecting electrode 52 of light-emitting OLED elements 80. The segments of electron injecting/contact layers 52, 54 (and of ITO segments 20, if segmented) are thus of like pitch over the length and breadth of sheet 10, but segments of layer 54 are preferably offset slightly so that each segment 54 overlies a contact region at which connection may be made to electrode 52.

Top electrode 52 may be a layer of magnesium, magnesium/silver, calcium, calcium/aluminum, lithium fluoride or lithium fluoride/aluminum, or any other stable electron injector. Contact layer 54 may be aluminum, gold, chromium, chromium/gold (Cr Au) or copper, for example, or any other durable high-conductivity material. Top electrodes 52 and contacts 54 are in one-to-one correspondence with one another and with a portion of ITO layer 20, separated by a light-emitting material layer 40, along the length of a conductor 30 over the length and breadth of sheet 10. It is noted that contacts or connection sites of contacts 50 may simply be locations designated such on conductor layer 54 or may be sites at which additional thickness of the conductive material of layer 54 or other compatible conductive material is build up for providing a more durable contact.

In the arrangement of FIG. 5A, contacts 50 provide a durable contact structure to which conductors providing pixel data signals are connected, which data signal conductors (not shown) may be by conductors on bent or planar printed wiring circuit boards, flexible cables, flexible circuit boards or other convenient structure brought against contacts 50. Such connection structures typically include conductors that lie transverse to the length direction of conductors 30 of light-emitting display 90.

Alternatively, as shown in FIG. 5B, contacts 50 may be conductive strips 50′ disposed transverse to the direction of conductors 30 so that connection thereto may be made at or near an edge of sheet 10. Contact strips 50′ may be applied either before or after the patterned layer of insulation 60. Because there is no active OLED material under the portion of contact 50′ at the edge of display 90, the connecting of data signal conductors to such contact strips 50′ cannot cause a short circuit through or damage to OLED layer 40 in any region between the hole injecting electrode layer 20 and the electron injecting electrode 52 of any light-emitting element 80. The deposition of contact layer 54 may also be patterned to produce respective contacts to conductors 30 at one or both ends 18 of sheet 10 for connecting to ITO electrode 20, 20′ through hole 62 (e.g., where there is no OLED layer 30 or insulator material 60 overlying ITO electrode layer 20 and/or conductor 30 at the end 18 of sheet 10) to provide a durable contact structure to which conductors providing pixel select signals are connected.

Thus, suitable electrical connections can be made to couple the select signal and the data signal to respective electrodes 20 and 52 of each light-emitting element 80 for controllably and selectively energizing each light-emitting element 80 to produce the pixels of an image to be displayed by a display 90, 90′ including an array of a plurality of light-emitting elements 80. These connections are made to the surface of the sheet-like light-emitting display 90 on which the light-emitting elements are formed, and the light L emitted thereby passes through sheet 10 away from the light-emitting elements 80 to be observed by a viewer of such display. It is noted that because light-emitting display 90, 90′ may be of any desired length and width, a thin panel display of virtually any desired size (height and width) may be provided utilizing the present invention.

Light emitted by light-emitting element 80, while generated in OLED material 40, passes through the ITO or other thin material of electrode 20 and through sheet 10 to be observed by a viewer of the display including light-emitting display 90, as is indicated by arrows L. The presence of top electrode 52 and/or contact layer 54 overlying OLED layer 40 desirably reflects light from OLED material 40 and so tends to increase the light output along the direction of arrow L.

Where light-emitting display 90 is utilized in a color display, light-emitting elements 80 emitting three different colors of light, such as red (R), green (G) and blue (B), are utilized. The three different color light-emitting elements 80R, 80G, 80B are arranged to be in adjacent sets of R, G, B elements, each set providing a color pixel. Such arrangement of light-emitting elements 80R, 80G, 80B may be provided by sequencing R, G and B OLED materials 40 in the direction along the length of each conductor 30 or may be provided by placing different OLED materials 40 in strips (rows) parallel to conductors 30 in an R-G-B sequence. In other words, any arrangement disposing or grouping a red-emitting pixel 80R near a green-emitting pixel 80G near to a blue-emitting pixel 80B, and so forth, is satisfactory.

Suitable small molecule OLED structures are known and include ITO as the hole injector, green-emitting OLED fabricated from naththyl-substituted benzidine derivative (NPB) as the hole transport layer, tris-(8-hydroxyquinoline) aluminum (Alq₃) as the electron transport layer, and magnesium/silver as the cathode, which are available commercially from Aldrich Chemical Company located in Milwaukee, Wisconsin and are reported by E. W. Forsythe et al in Extended Abstracts of The Fourth International Conference on the Science and Technology of Display Phosphors & 9th International Workshop on Inorganic and Organic Electroluminescence, Sep. 14-17, 1998, at page 53.

Red emission is obtained by doping the Alq₃ layer in the foregoing OLED structure doped with 6% 2,3,7,8,12,13,17,18-octaethyl-21H,23H-porphine platinum (II) (PtOEP) as reported by D. F. O'Brien et al in the Extended Abstracts of The Fourth International Conference on the Science and Technology of Display Phosphors & 9th International Workshop on Inorganic and Organic Electroluminescence, Sep. 14-17, 1998, at page 37 et seq. Blue emission is obtained in the foregoing OLED structure by including an additional layer. This OLED structure includes spiro-linked TAD (spiro-TAD) as the hole transport layer, spiro-linked sexiphenyl (spiro-6Φ) as the blue emitter layer, and Alq₃ as the electron transport layer as reported by Frank Weissortel et al in Extended Abstracts of The Fourth International Conference on the Science and Technology of Display Phosphors & 9th International Workshop on Inorganic and Organic Electroluminescence, Sep. 14-17, 1998, at page 5 et seq.

Small-molecule OLED materials may be applied by evaporation and polymer OLED materials may be deposited as monomers, for example, using ink jet printing, roller coating, screen printing and the like to deposit mixtures of the OLED material and suitable solvents as is known, and subsequently evaporating the solvent(s) and polymerizing the monomer by heating. Alternatively, a polymer film could be directly deposited from solution.

For a polymer OLED structure, ITO may be employed as the hole injector layer and polyethylene dioxythipene, commonly known as PEDOT, doped with polystyrene sulfonic acid (PEDOT:SS) available from by Bayer A. G. located in Ludwigshafen, Germany, or PVK poly-N-carbazole available from Aldrich Chemicals, as the hole transport layer. The electron transport/emissive layer can by a poly(fluorene)-based polymer for green emission, and other polymers for red and blue emission, as reported by J. H. Burroughes in the Extended Abstracts of The Fourth International Conference on the Science and Technology of Display Phosphors & 9th International Workshop on Inorganic and Organic Electroluminescence, Sep. 14-17, 1998, at page 133 et seq. A thin layer of a material that enhances hole injection, such as of copper pthalocyanine, e.g., about 100 Å thick, may be utilized.

Such green-emitting OLED materials typically provide brightness levels of about 100 cd/m² and exhibit power efficiencies of about 1, 11 and 5 lumens/watt for the R, G and B materials, respectively.

While certain exemplary light-emitting materials are described, the light-emitting materials that may be employed in the invention are not limited thereby. Other light-emitting materials, including but not limited to polymer and small molecule materials, may also be employed.

Preferably, because the area of each of the light-emitting elements 80 is desirably as large as possible to maximize the light produced and therefore the brightness of the display in which light-emitting display 90 is employed, rectangular elements 80 having edges close to the edges of adjacent elements 80 on sheet 10 are desirable. Similarly, the portions of insulation layer 60 defining or filling the spaces between adjacent elements 80 are made narrow for increasing the area of elements 80 relative to the area of top surface 12 consistent with tolerances and the width that is appropriate for insulation between adjacent elements 80 and contact with electrode 52 and contact 54.

Insulation layer 60, which prevents or reduces moisture and other undesirable material from reaching the OLED light-emitting elements 80 while not interfering with the making of electrical connection thereto, furthers achieving long life and high performance of the OLED light-emitting elements 80. Suitable moisture barrier materials include silicon nitride, silicon dioxide, silicon oxynitride, silicon carbide, diamond-like carbon, and phosphorus-silicate glass, and are typically applied by evaporation or sputtering through a mechanical mask.

Alternatively, insulation layer 60 may be formed of an organic layer, such as a layer of a photoresist material. The photoresist may be deposited by dip coating and/or spraying or other suitable method and then be exposed and developed, and then partially removed to form openings, e.g., openings exposing ITO electrode layer 20 or OLED layer 40. The photoresist may also be selectively deposited, such as by screen printing or ink jet printing, in the pattern of layer 60. Another suitable type of material for insulation layer 60 is an epoxy that is selectively deposited in the desired pattern and is then cured by exposure to ultra-violet light. In each case, however, the patterned photoresist layer 60 if first made remains in place during the deposition of the OLED stack 40 and the electrode layer 52 and contact layer 54, and so must be processed to be fully compatible with the OLED and electrode materials and the processing thereof.

Insulation layer 60 may also define an opening 62 at one or both ends 18 of sheet 10 at which ends of ITO layer 20 and/or conductor 30 are exposed for later making electrical connection to the hole-injecting electrode 20 of light-emitting elements 80 and to electrical conductor 30 providing a relatively high conductivity connection thereto. At least a layer 54 of high-conductivity material is preferably deposited through opening 62 so as to provide a high-conductivity connection to high-conductivity longitudinal conductor 30.

In addition, it may be desirable for conductor 30 to also be deposited so as to overlie the portion of ITO layer 20 near end 18 of sheet 10 that will be exposed through opening 62. Electrical bus 30, which couples a drive signal to the ITO electrodes 20 of each light-emitting element 80 along the length of sheet 10, is preferably covered by insulation layer 60 for providing electrical insulation thereof.

FIG. 6 is an end view schematic diagram illustrating an alternative exemplary arrangement and a certain alternative step in a sequence of exemplary steps for making a display 90 in accordance with the invention. In this alternative, ITO layer 20′ is deposited before conductor 30 is formed and extends into grooves 14 so that later formed conductor 30 overlies the portion of ITO layer 20 that is in groove 14 so as to make electrical connection thereto. Grooves 14 may have sloped sides and/or rounded edges, as illustrated, to facilitate continuity of ITO layer 20′.

FIG. 7 is an end view schematic diagram illustrating a certain alternative step in a sequence of exemplary steps subsequent to the exemplary step of FIG. 6 and illustrating an exemplary display 90 in accordance with the invention. OLED layer 40, contact layers 50, 52, 54 are as described above, except that a patterned OLED layer 40 is illustrated, and so insulation later 60 extends down to conductor 30, thereby to insulate the edges of OLED layer segments 40 and contacts 50, 52, 54.

In all other respects, the elements of FIGS. 6 and 7 are the same in material and function as those described above in relation to FIGS. 4 and 5A-5B.

While the present invention has been described in terms of the foregoing exemplary embodiments, variations within the scope and spirit of the present invention as defined by the claims following will be apparent to those skilled in the art. For example, while the substrate is generally referred to as a sheet 10, any suitable form of a planar substrate, such as a wide strip, roll or the like, may be utilized as may be convenient for processing sheets singly or in batches or strips or rolls in a substantially continuous reel-to-reel process. Displays 90 made in sheet, roll or other form may by sized for utilization or may be cut or otherwise separated into two or more smaller displays of a desired size and/or shape. While a large sheet or very wide roll of material may be utilized for making a large-screen display 90, such as for large-screen television, public announcement displays for billboards, airports, highways, stadia and the like, smaller displays may be utilized for computer monitors, cell phones, personal assistants, electronic notepads, Internet access appliances and the like.

Further, while the features on sheet 10 are referred to as grooves 14, ridges 16 and/or lands 16, any arrangement of alternating raised regions and depressed regions that allows the forming of a conductor 30 is suitable, whether of uniform or nonuniform width and/or depth, and whether substantially parallel or not, and grooves, lands and ridges are intended to encompass all such suitable features. In fact, the present invention may be employed for displays of nonuniform and/or nonstandard size and shape as may be convenient for an intended utilization, and can be flexible where sheet 10 is flexible so as to be conformed to whatever structure display 90 may be mounted or attached.

It is also noted that FIG. 4 illustrates a continuous OLED layer 40 and FIG. 6 illustrates a segmented or striped OLED layer 40, however, either alternative arrangement of OLED layer 40 may be utilized in any of the embodiments of the invention. Similarly, insulation layer 60 may be deposited as a pattern or as a layer that is subsequently patterned, and may be deposited either before or after contact layers 50, 52, 54. Further, insulation layer 60 may be deposited before or after OLED layer 40, but must be deposited after OLED layer 40 where OLED layer 40 is not patterned, but is continuous.

In addition, top electrode layer 52 and/or contact layer 54 thereon may be formed as segments as illustrated, e.g., using a mechanical mask, or may be deposited in a continuous strip along the length of display 90 which is later segmented by scribing transverse gaps, e.g., over portions of insulation layer 60. Such scribing can be by mechanical scribing, by laser scribing, or by a fine saw, for example.

Further, if it is desired that ITO layer 20 be segmented to correspond to the segments of electrode material 52 and/or contact material 54, such may be provided by evaporating or sputtering layer 20 through a mechanical mask. Alternatively, a continuous ITO layer 20 may be formed and then be striped or segmented, such as by wet or dry or chemical etching using a photoresist or a mechanical mask to define the pattern thereof. One patterning method is to etch the material on sheet 10 to be removed by exposing it to a plasma through openings in a mechanical mask, wherein the turbulence of the etching plasma tends to produce a tapered edge, rather than a sharp or abrupt edge. Material to be so removed may include, e.g., ITO layer 20, insulating material 60, light-emitting material 40, electrode material 52, and/or contact material 54.

What is claimed is:

1. A display comprising:
an optically transparent material having a broad surface having a plurality of elongated recesses therein defining raised portions therebetween;
an electrode layer disposed on the raised portions of the broad surface of said optically transparent material, wherein said electrode layer includes an optically-transparent electrically-conductive material;
a plurality of elongated electrical conductors disposed in the plurality of elongated recesses of the broad surface of said optically transparent material,
wherein a respective one of said elongated electrical conductors is in electrical contact with said electrode layer on one of the raised portions;
a light-emitting material disposed at least on the electrode layer on the raised portions of said optically-transparent material; and
a plurality of electrical contacts disposed on the light-emitting material on the raised portions of said optically-transparent material,
wherein the light-emitting material disposed between said electrode layer and a given one of said electrical contacts emits light responsive to an electrical signal applied between said electrode layer and said corresponding one electrical contact.

2. The display of claim 1 further comprising insulating material disposed for insulating portions of the light-emitting material not covered by said plurality of electrical contacts.

3. The display of claim 2 wherein said insulating material includes at least one of silicon nitride, silicon dioxide, silicon oxynitride, silicon carbide, diamond-like carbon, phosphorus-silicate glass, photoresist, and ultraviolet curable epoxy.

4. The display of claim 1 wherein said electrode layer includes one of strips and segments of the optically-transparent electrically conductive material.

5. The display of claim 1 wherein said electrode layer extends into ones of the plurality of elongated recesses and underlies a one of said plurality of elongated electrical conductors disposed therein.

6. The display of claim 1 wherein at least one of:
the optically-transparent electrically conductive material includes at least one of indium tin oxide, tin oxide, zinc oxide, a noble metal, PEDT, polyaniline, polythiophane, and combinations thereof, and
said electrical contacts include at least one layer of at least one of magnesium, magnesium/silver, calcium, calcium/aluminum, lithium fluoride, lithium fluoride/aluminum, aluminum, gold, silver, copper, chromium, chromium/gold, tungsten, alloys thereof, and combinations thereof.

7. The display of claim 1 wherein the optically-transparent material includes at least one of glass, borosilicate glass, soda-lime glass, quartz, sapphire, plastic, polymethyl-methacrylate (PMMA), polycarbonate, acrylic, Mylar, polyester, and polyimide.

8. The display of claim 1 wherein said plurality of electrical contacts include one of strips transverse to said elongated electrical conductor and of segments.

9. The display of claim 1 wherein said elongated electrical conductor includes at least one of aluminum, gold, silver, copper, chromium, tungsten, alloys thereof, electrically-conductive epoxy, electrically-conductive adhesive, and combinations thereof.

10. The display of claim 1 wherein said light-emitting material includes one of an inorganic electro-luminescent material and an organic light-emitting material.

11. The display of claim 2 wherein said electrical contacts extend beyond an edge of said light-emitting material so as to be disposed at least partly on said layer of insulating material.

12. The display of claim 1 further comprising at least one further electrical contact disposed proximate a first end of said plurality of elongated conductors on and in direct electrical contact with said electrode layer without intervening light-emitting material.

13. A sheet-like display having a plurality of light-emitting elements disposed thereon comprising:
a sheet of an optically transparent material having a broad surface and a plurality of elongated substantially parallel recesses therein defining elongated substantially parallel raised portions therebetween;
a patterned electrode layer defining electrodes disposed on respective elongated raised portions of the broad surface of said optically transparent material,
wherein said patterned electrode layer includes one of segments and strips of an optically-transparent electrically-conductive material;
a plurality of elongated electrical conductors disposed in the plurality of elongated substantially parallel recesses of the broad surface of said sheet,
wherein a respective one of said elongated electrical conductors is in electrical contact with the one of said electrodes disposed on the one of the raised portions contiguous the one of the elongated recesses including said respective one of said electrical conductors;
a light-emitting material disposed at least on said patterned electrode layer on the raised portions of said sheet; and
a pattern of electrical contacts disposed on said light-emitting material on the raised portions of said optically-transparent material,
said pattern of electrical contacts including at least one of contact segments and contact strips,
wherein said contact strips are disposed in a direction transverse to the elongated direction of said plurality of elongated electrical conductors,
wherein the light-emitting material disposed between corresponding ones of said electrodes and said electrical contacts emits light responsive to an electrical signal applied between a corresponding one of said elongated electrical conductors and the corresponding one of said electrical contacts.

14. The sheet-like display of claim 13 further comprising insulating material disposed for insulating portions of said light-emitting material not covered by said pattern of electrical contacts.

15. The sheet-like display of claim 14 wherein said insulating material includes at least one of silicon nitride, silicon dioxide, silicon oxynitride, silicon carbide, diamond-like carbon, phosphorus-silicate glass, photoresist, and ultraviolet curable epoxy.

16. The sheet-like display of claim 13 wherein said patterned electrode layer extends into ones of the plurality of elongated substantially parallel recesses and underlies a one of said plurality of elongated electrical conductors disposed therein.

17. The display of claim 13 wherein said elongated electrical conductor includes at least one of aluminum, gold, silver, copper, chromium, tungsten, alloys thereof, electrically-conductive epoxy, electrically-conductive adhesive, and combinations thereof.

18. The sheet-like display of claim 13 wherein at least one of:
the optically-transparent electrically conductive material includes at least one of indium tin oxide, tin oxide, zinc oxide, a noble metal, PEDT, polyaniline, polythiophane, and combinations thereof, and
said plurality of electrical contacts include at least one layer of at least one of magnesium, magnesium/silver, calcium, calcium/aluminum, lithium fluoride and lithium fluoride/aluminum, aluminum, gold, silver, copper, chromium, chromium/gold, tungsten, alloys thereof, and combinations thereof.

19. The sheet-like display of claim 13:
wherein the optically-transparent material includes at least one of glass, borosilicate glass, soda-lime glass, quartz, sapphire, plastic, polymethyl-methacrylate (PMMA), polycarbonate, acrylic, Mylar, polyester, and polyimide, and
wherein said elongated electrical conductor includes at least one of aluminum, gold, silver, copper, chromium, tungsten, alloys thereof, and combinations thereof.

20. The sheet-like display of claim 13 wherein said light-emitting material includes one of an inorganic electro-luminescent material and an organic light-emitting material.

21. The sheet-like display of claim 13 further comprising at least one further electrical contact disposed proximate a first end of said plurality of elongated conductors on and in direct electrical contact with at least one of said electrodes without intervening light-emitting material.

22. A method for making a light-emitting sheet having a plurality of light-emitting elements thereon comprising:
providing a sheet of electrically insulating material having on a first surface thereof a plurality of elongated recesses defining ridges therebetween;
depositing first electrodes at least on the ridges of the first surface;
placing electrically conductive material in the elongated recesses and in electrical contact with a proximal one of the first electrodes;
depositing a light-emitting material at least on the first electrodes; and
depositing a pattern of electrical contacts on the light-emitting material and substantially overlying the first electrodes.

23. The method of claim 22 wherein:
said depositing a pattern of electrical contacts includes first depositing a pattern of second electrodes on the layer of light-emitting material substantially overlying the first electrodes, and
then depositing a pattern of metal electrical contacts on the second electrodes.

24. The method of claim 23 wherein said depositing a pattern of metal electrical contacts includes depositing strips of metal contact material lying in a direction transverse to the elongated recesses and making electrical contact with a plurality of the second electrodes.

25. The method of claim 22 further including applying an insulating material at least on portions of the light-emitting material not having the pattern of electrical contacts thereon,
whereby the light-emitting material is covered by the electrical contacts and the insulating material.

26. The method of claim 25 wherein said applying an insulating material includes depositing at least one of silicon nitride, silicon dioxide, silicon oxynitride, silicon carbide, diamond-like carbon, phosphorus-silicate glass, photoresist, and ultraviolet curable epoxy.

27. The method of claim 22:
wherein said depositing first electrodes includes depositing at least one of indium tin oxide, tin oxide, zinc oxide, a noble metal, PEDT, polyaniline, polythiophane, and combinations thereof, and
wherein said depositing a pattern of electrical contacts includes depositing at least one of magnesium, magnesium/silver, calcium, calcium/aluminum, lithium fluoride, lithium fluoride/aluminum, aluminum, gold, silver, copper, chromium, chromium/gold, tungsten, alloys thereof, and combinations thereof.

28. The method of claim 22 further comprising patterning at least one of the first electrodes and the pattern of electrical contacts by one of scribing, laser scribing, photo etching, plasma etching, wet chemical etching and dry chemical etching.

29. The method of claim 22 wherein said providing a sheet of electrically insulating material includes:
providing the sheet of electrically insulating material, and
forming the plurality of elongated recesses therein by one of extrusion, pressing, embossing, machining, mechanical machining, laser machining, grinding, and etching.

30. A method for making a display on a flat sheet comprising:
forming alternating lands and grooves in the flat sheet;
depositing a first electrically-conductive material in the grooves;
depositing a thin layer of optically transparent second electrically-conductive material on the lands,
wherein the second electrically-conductive material on the lands and the first electrically-conductive material in the grooves adjacent thereto are electrically connected at least at a plurality of locations;
depositing a light emitting material on the second electrically-conductive material on the lands, wherein at least one of the second electrically-conductive material and the light emitting material is segmented to define pixel areas;
depositing a layer of a third electrically-conductive material on the light emitting material to provide a plurality of contacts thereon each associated with a respective pixel area; and
depositing a layer of insulating material over the light emitting material except on at least a portion of the contacts thereon.
